(19) United States
(12) Patent Application Publication
(10) Pub. No.: US 2011/0291220 A1
(43) Pub. Date: Dec. 1, 2011

(54) SOLID-STATE IMAGING DEVICE

(75) Inventor: Takeshi YOSHIDA, Kanagawa (JP)

(73) Assignee: Kabushiki Kaisha Toshiba, Tokyo (JP)

(21) Appl. No.: 13/052,163

(22) Filed: Mar. 21, 2011

(30) Foreign Application Priority Data
May 25, 2010 (JP) 2010-119418

(51) Int. Cl. H01L 31/102

(52) U.S. Cl. 257/461; 257/E31.055

(57) ABSTRACT

According to one embodiment, a solid-state imaging device includes a first diffusion layer for accumulating carriers generated by a photoelectric effect; a second diffusion layer adjoining the first diffusion layer, the second diffusion layer having a polarity opposite to that of the first diffusion layer; and a reference voltage setting unit that applies a changing voltage that temporally changes to the first diffusion layer through the second diffusion layer and sets a voltage based on an amplitude of the applied changing voltage as a reference voltage of the first diffusion layer.

### CROSS-REFERENCE TO RELATED APPLICATIONS

This application is based upon and claims the benefit of priority from the prior Japanese Patent Application No. 2010-119418, filed on May 25, 2010; the entire contents of which are incorporated herein by reference.

### FIELD

Embodiments described herein relate generally to a solid-state imaging device.

### BACKGROUND

Demand for a CMOS image sensor as a camera component of a mobile phone is increasing greatly, and its image quality and performance are also being highly developed. In the related art, as the image quality is improved, the number of pixels in the CMOS image sensor accordingly increases, and thus there is a great demand for the miniaturization of a unit pixel of the CMOS image sensor.

### BRIEF DESCRIPTION OF THE DRAWINGS

FIG. 1 is a block diagram illustrating a configuration of main parts of a CMOS image sensor according to a first embodiment of the invention;

FIG. 2 is an equivalent circuit diagram illustrating a configuration of the unit pixel of FIG. 1;

FIG. 3 is a plan view illustrating the unit pixel of FIG. 2;

FIG. 4 is a diagram illustrating a cross-sectional structure of the area corresponding to a single pixel of a solid-state imaging device of the CMOS image sensor of FIG. 1;

FIG. 5 is a diagram illustrating a timing chart of a voltage signal applied to a reset signal line and a read signal line;

FIG. 6 is a diagram illustrating a method of manufacturing a solid-state imaging device including the unit pixel of FIG. 1;

FIG. 7 is a diagram illustrating a method of manufacturing a solid-state imaging device including the unit pixel of FIG. 1;

FIG. 8 is a diagram illustrating a method of manufacturing a solid-state imaging device including the unit pixel of FIG. 1;

FIG. 9 is a diagram illustrating a method of manufacturing a solid-state imaging device including the unit pixel of FIG. 1;

FIG. 10 is a diagram illustrating a method of manufacturing a solid-state imaging device including the unit pixel of FIG. 1;

FIG. 11 is a diagram illustrating a method of manufacturing a solid-state imaging device including the unit pixel of FIG. 1;

FIG. 12 is a diagram illustrating a method of manufacturing a solid-state imaging device including the unit pixel of FIG. 1;

FIG. 13 is an equivalent circuit diagram illustrating a configuration of the unit pixel according to a second embodiment of the invention;

FIG. 14 is a plan view illustrating the unit pixel of FIG. 13;

FIG. 15 is a diagram illustrating a cross-sectional structure of the area corresponding to a single pixel of the solid-state imaging device of the CMOS image sensor according to the second embodiment of the invention;

FIG. 16 is a diagram illustrating a method of manufacturing a solid-state imaging device having the unit pixel of FIG. 14;

FIG. 17 is a diagram illustrating a method of manufacturing a solid-state imaging device having the unit pixel of FIG. 14;

FIG. 18 is a diagram illustrating another cross-sectional structure of the area corresponding to a single pixel of a solid-state imaging device of a CMOS image sensor according to the second embodiment of the invention;

FIG. 19 is an equivalent circuit diagram illustrating a configuration of a unit pixel according to a third embodiment of the invention;

FIG. 20 is a plan view illustrating a unit pixel of FIG. 19;

FIG. 21 is a diagram illustrating a cross-sectional structure of the area corresponding to a single pixel of a solid-state imaging device of a CMOS image sensor according to the third embodiment of the invention;

FIG. 22 is a diagram illustrating a method of manufacturing a solid-state imaging device of a part of the unit pixel of FIG. 21;

FIG. 23 is a plan view illustrating a CMOS image sensor of a two-pixel one-cell structure of the related art; and

FIG. 24 is a plan view illustrating the CMOS image sensor when the first embodiment of the invention is applied to the two-pixel one-cell structure.

### DETAILED DESCRIPTION

In general, according to one embodiment, a solid-state imaging device includes a first diffusion layer that accumulates carriers generated by a photoelectric effect and a photodiode formed on a substrate. The solid-state imaging device according to the present embodiment includes a second diffusion layer adjoining the first diffusion layer, the second diffusion layer having polarity opposite to that of the first diffusion layer. The solid-state imaging device according to an embodiment of the invention includes a first reference voltage setting unit connected to the second diffusion layer through a wiring line, the first reference voltage setting unit applying a changing voltage that temporally changes abruptly to the first diffusion layer through the wiring line and the second diffusion layer and setting the voltage based on an amplitude of the applied changing voltage as a reference voltage of the first diffusion layer.

Exemplary embodiments of a solid-state imaging device will be explained below in detail with reference to the accompanying drawings. The present invention is not limited to the following embodiments.

### First Embodiment

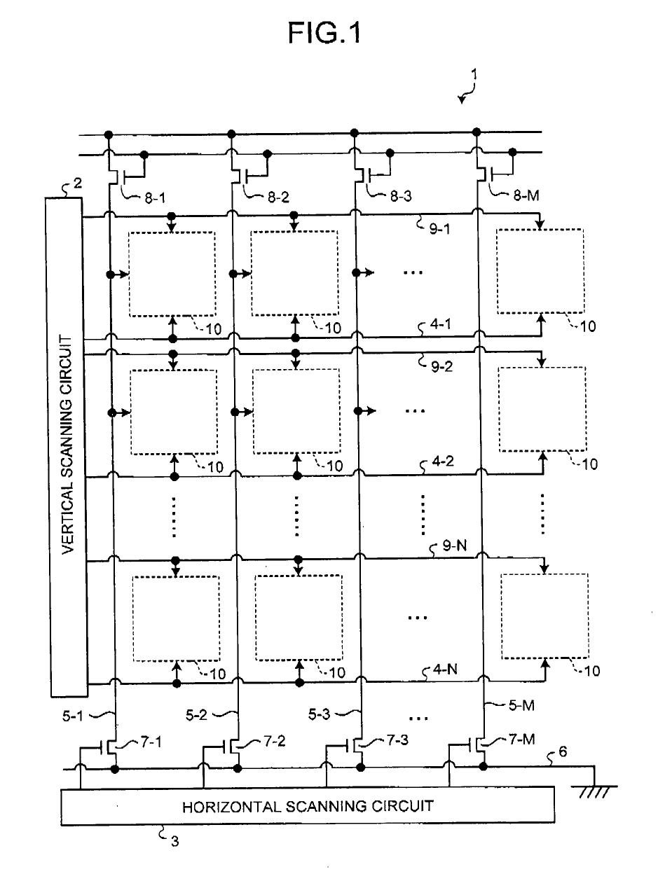

FIG. 1 is a block diagram illustrating a configuration of main parts of a CMOS image sensor having a solid-state imaging device according to a first embodiment of the invention.

As shown in FIG. 1, the CMOS image sensor 1 according to a first embodiment of the invention includes a plurality of unit pixels 10 arranged in an array shape of M columns and N rows, a vertical scanning circuit 2, and a horizontal scanning circuit 3.

The CMOS image sensor 1 has M vertical signal lines 5-1 to 5-M to which output terminals of each unit pixel 10 of a single column are connected in parallel for each column of the unit pixel 10.

The CMOS image sensor 1 has N reset signal lines 4-1 to 4-N and read signal lines 9-1 to 9-N to which input terminals of each unit pixel 10 of a single row are connected in parallel for each row of the unit pixel 10.

The vertical scanning circuit 2 sequentially selects each row of the unit pixel 10 at a determined timing. The vertical scanning circuit 2 individually controls the reset signal line 4 and the read signal line 9 for the selected single row to activate each unit pixel 10. The vertical scanning circuit 2 applies a pulse voltage to each unit pixel 10 by applying a pulse voltage to the reset signal lines 4-1 to 4-N. The pulse voltage applied by the vertical scanning circuit 2 to the reset signal lines 4-1 to 4-N has a waveform abruptly changing up and down in time. This pulse voltage rises to a value equal to or higher than a predetermined threshold voltage and then falls to a predetermined voltage VSS.

The horizontal scanning circuit 3 selects the selection transistors 7-1 to 7-M corresponding to each column of the unit pixel 10 at specified timings. The horizontal scanning circuit 3 reads the pixel signal of each unit pixel 10 of a single pixel corresponding to the vertical signal line 5-1 to 5-M connected to the selected selection transistor 7-1 to 7-M. In addition, one end of the vertical signal line 5-1 to 5-M is provided with a load transistor 8-1 to 8-M, respectively. The other end of the vertical signal line is connected to the horizontal signal line 6 through the selection transistor 7-1 to 7-M.

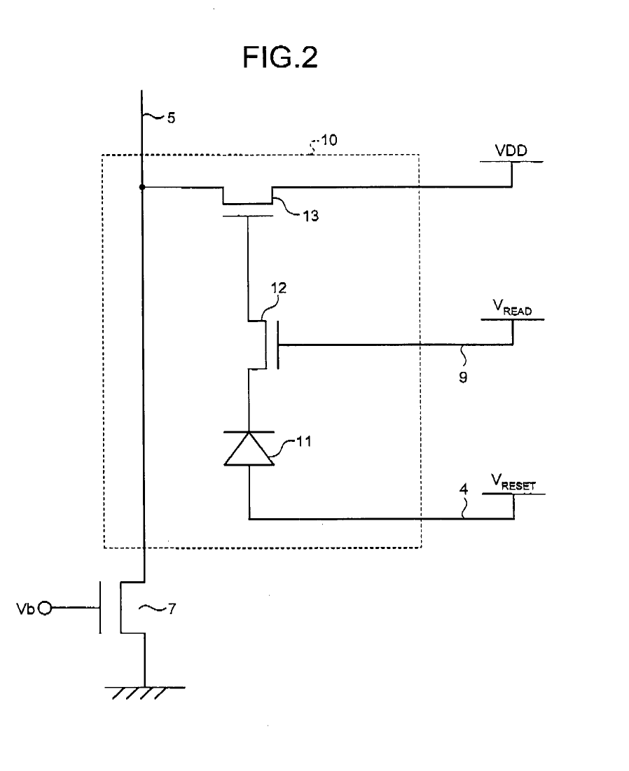

Next, a configuration of the unit pixel 10 will be described with reference to FIG. 2. FIG. 2 is an equivalent circuit diagram illustrating a configuration of the unit pixel 10 of FIG. 1.

As shown in FIG. 2, the unit pixel 10 includes a photodiode 11, a read transistor 12, and an amplification transistor 13.

The photodiode 11 photo-electrically converts the incident light into a signal charge amount corresponding to the light amount thereof and accumulates it. The anode terminal of the photodiode 11 is connected to the reset signal line 4. The cathode terminal of the photodiode 11 is connected to the source terminal of the read transistor 12.

The read transistor 12 is controlled to be turned on/off based on a voltage of the read signal line 9 connected to the gate terminal of the read transistor 12. The read transistor 12 reads the signal charge converted and accumulated by the photodiode 11 during an ON period.

The source terminal of the amplification transistor 13 is connected to a power voltage V_{DD}. The drain terminal of the amplification transistor 13 is connected to the vertical signal line 5. The gate terminal of the amplification transistor 13 is connected to the drain terminal of the read transistor 12. The amplification transistor 13 converts the voltage (converted signal voltage) read by the read transistor 12, when the selection transistor 7 is turned on, into a pixel signal of the same level and outputs it to the vertical signal line 5.

The reset signal line 4 applies the pulse voltage from the vertical scanning circuit 2 into the anode terminal of the photodiode 11. This pulse voltage temporally rises to a value equal to or higher than the predetermined threshold voltage and then falls to the voltage VSS.

The vertical scanning circuit 2 applies the voltage rising to the threshold voltage or higher to the reset signal line 4 as a pulse voltage when it is read. The vertical scanning circuit 2 applies the voltage falling to the voltage VSS or lower to the reset signal line 4 as a pulse voltage after it is read, and maintains the voltage VSS until the next timing.

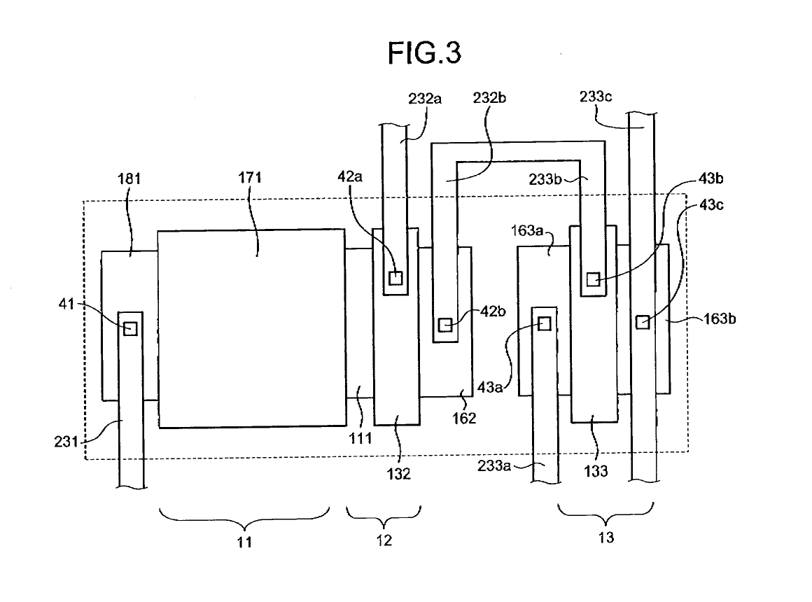

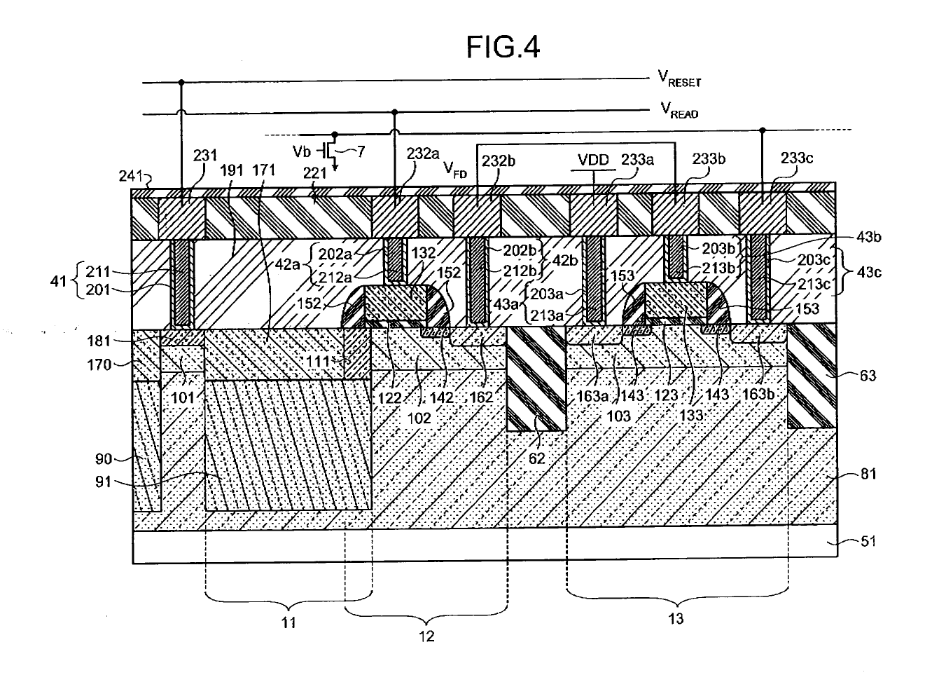

Next, the structure of the unit pixel 10 will be described in detail with reference to FIGS. 3 and 4. FIG. 3 is a plan view illustrating the unit pixel of FIG. 2. FIG. 4 is a diagram illustrating a cross-sectional structure of the area corresponding to a single pixel of the solid-state imaging device of the CMOS image sensor of FIG. 1. In FIG. 3, the uppermost protection film, the interlayer films for burying each of gaps between each gate terminal layers and gaps between wiring layers, and the side walls are not shown intentionally.

As shown in FIGS. 3 and 4, in the solid-state imaging device corresponding to the unit pixel 10, a P-type electrolysis layer 81 for electrically separating the photodiode 11 is formed on the substrate 51 which is a P-type Si substrate. In the area corresponding to the photodiode 11 on the substrate 51, an N-type carrier accumulation side diffusion layer 91 for accumulating carriers generated by the photoelectric effect, a P-type shield diffusion layer 171 for protecting the carrier accumulation side diffusion layer 91 from an interface state of the substrate 51, and a well 101, and a P-type contact bonding layer 181 are formed.

The contact bonding layer 181 is formed on the well 101. The contact bonding layer 181 contains P-type impurities with a higher concentration than that of the well 101. A contact 41 is formed on the contact bonding layer 181. A wiring line 231 for connecting to the reset signal line 4 is formed on the contact 41. In the area corresponding to the photodiode 11, each diffusion layer is formed such that all sides of the carrier accumulation side diffusion layer 91 are surrounded by the P-type diffusion layer having an inverted polarity to that of the carrier accumulation side diffusion layer 91. All sides of the carrier accumulation side diffusion layer 91 are surrounded by the shield diffusion layer 171 and the electrolysis layer 81 which is a P-type diffusion layer. In addition, in the left side of FIG. 4, the shield diffusion layer 170 and the carrier accumulation side diffusion layer 90 included in the neighboring unit pixel are also illustrated.

A channel 102 is formed in the area corresponding to the read transistor 12. A gate oxide layer 122 is formed on the channel 102. The gate electrode 132 of the read transistor 12 is formed on the gate oxide layer 122.

A contact 42a is formed on the gate electrode 132. A wiring line 232a for connecting to the read signal line 9 is formed on the contact 42a.

An N⁺ diffusion layer 162 is formed on the substrate 51 in the side of the drain of the gate electrode 132. A contact 42b is formed on the N⁺ diffusion layer 162. A wiring line 232b is formed on the contact 42b. The wiring line 232b is connected to the wiring line 233b of the area corresponding to the amplification transistor 13.

In the source region of the read transistor 12, a buried N-type diffusion layer 111 making contact with, the carrier accumulation side diffusion layer 91 is formed. In addition, a side wall 152 is formed in the side wall of the gate electrode 132. A lightly-doped drain (LDD) diffusion layer 142 is formed on the substrate 51 under the side wall 152.

The area corresponding to the amplification transistor 13 is separated by the element isolations 62 and 63 from the area of the read transistor 12 and the amplification transistor of the neighboring unit pixel. A channel 103 is formed in the area corresponding to the amplification transistor 13. A gate oxide layer 123 is formed on the channel 103. A gate electrode 133 of the amplification transistor 13 is formed on the gate oxide layer 123.

An N⁺ diffusion layer 163a is formed on the substrate 51 in the source side of the gate electrode 133. A contact 43a is formed on the N⁺ diffusion layer 163a. A wiring line 233a for connecting to the power voltage V_{DD} is formed on the contact 43a. A contact 43b is formed on the gate electrode 133. A wiring line 233b is formed on the contact 43b.

An N⁺ diffusion layer 163b is formed on the substrate 51 in the drain side of the gate electrode 133. A contact 43c is formed on the N⁺ diffusion layer 163b. A wiring line 233c is formed on the contact 43c. The wiring line 233c is connected to the selection transistor 7. In addition, similar to the gate electrode 132, a side wall 153 is formed in the side wall of the gate electrode 133. A lightly-doped drain (LDD) diffusion layer 143 is formed in the subtracted 51 under the side wall 153.

An insulative interlayer film 191 is buried in each of the gaps between the gate terminal layers and between the contacts. An insulative interlayer film 221 is buried in each gap between the wiring line layers. In addition, a protection film 241 is formed on each of the wiring line and the interlayer film 221. The contacts 41, 42a, 42b, and 43a to 43c have configurations for forming barrier metal layers 211, 212a, 212b, and 213a to 213c around the metal films 201, 202a, 202b, and 203a to 203c, respectively.

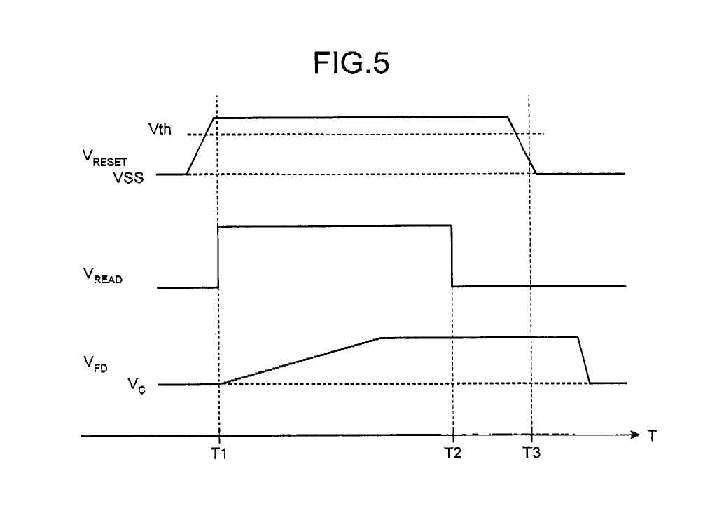

A reading process of this unit pixel 10 will now be described. FIG. 5 is a timing chart illustrating a voltage signal V_{RESET} applied to the reset signal line 4 and a voltage signal V_{READ} applied to the read signal line 9. FIG. 5 is a timing chart illustrating a read voltage V_{FD} containing the charges obtained by conversion and accumulation in the carrier accumulation side diffusion layer 91.

First, a read operation will be described. During the read operation, as shown in FIG. 5, the vertical scanning circuit 2 applies a high-level voltage to the read signal line 9 to turn the read transistor 12 on at the read initiating timing T1. At the same time, the vertical scanning circuit 2 applies, to the reset signal line 4, a pulse voltage abruptly rising from the voltage VSS with an amplitude higher than a predetermined threshold voltage Vth. The threshold voltage Vth is a voltage value corresponding to the reference voltage Vc for the carrier accumulation side diffusion layer 91, and the amplitude of the pulse voltage is obtained by adding a voltage value corresponding to an electric potential drop to the threshold voltage Vth.

This rising voltage is applied to the shield diffusion layer 171 through the wiring line 231 connected to the reset signal line 4, the contact 41, the contact bonding layer 181, and the well 101. As a result, a forward bias is applied to the PN junction formed in the P-type shield diffusion layer 171 and the N-type carrier accumulation side diffusion layer 91 adjoining the shield diffusion layer 171. As this applied voltage rises, the voltage V_{FD} of the carrier accumulation side diffusion layer 91 also rises. While the pulse voltage rises, the voltage V_{FD} is fixed to a voltage obtained by adding the voltage corresponding to the charges obtained by conversion and accumulation in the carrier accumulation side diffusion layer 91 and the reference voltage Vc. The read transistor 12 is turned on. For this reason, a voltage obtained by adding the voltage corresponding to the charges obtained by conversion and accumulation in the carrier accumulation side diffusion layer 91 and the reference voltage Vc through the read transistor 12 is amplified by the amplification transistor 13. As a result, it is possible to read a voltage corresponding to the charges obtained by conversion and accumulation in the carrier accumulation side diffusion layer 91.

Subsequently, the vertical scanning circuit 2 applies a low-level voltage to the read signal line 9 at a read end timing T2 to turn the read transistor 12 off. At the next timing T3, the vertical scanning circuit 2 applies a voltage abruptly falling from the rising voltage to the voltage VSS to the reset signal line 4.

When this falling voltage is applied, the PN junction formed in the carrier accumulation side diffusion layer 91 and the shield diffusion layer 171 is reverse-biased. For this reason, the voltage V_{FD} of the carrier accumulation side diffusion layer 91 is restored to the reference voltage Vc, and only the P-type diffusion layer is converged to the voltage VSS while the voltage V_{FD} is fixed to the reference voltage Vc. The vertical scanning circuit 2 is connected to the shield diffusion layer 171 through the wiring line 231 to temporally apply the pulse voltage to the shield diffusion layer 171 through the wiring line 231 and apply the pulse voltage to carrier accumulation side diffusion layer 91 so as to serve as a first reference voltage setting unit for setting a voltage based on the amplitude of the applied pulse voltage as a reference voltage of the carrier accumulation side diffusion layer 91.

In the related art, a reset transistor and a reset transistor connected to the drain terminal are further provided so that the voltage of the carrier accumulation side diffusion layer is fixed to the reference voltage again after reading the voltage corresponding to the charge obtained by conversion and accumulation in the carrier accumulation side diffusion layer.

In contrast, according to the first embodiment of the invention, the reset transistor of the related art may not be provided. According to the first embodiment of the invention, as described above, the reset signal line 4 is connected to the anode terminal of the photodiode 11, the vertical scanning circuit 2 can read a voltage corresponding to the charges obtained by conversion and accumulation in the carrier accumulation side diffusion layer 91 and fix the voltage of the carrier accumulation side diffusion layer 91 to the reference voltage just by applying a pulse voltage temporally abruptly changing to the unit pixel 10 through the reset signal line 4.

Therefore, according to the first embodiment of the invention, it is not necessary to provide an area for the reset transistor. For this reason, according to the first embodiment of the invention, it is possible to minimize the size of the unit pixel.

In addition, according to the first embodiment of the invention, it is possible to allocate the area for the reset transistor to the area of the carrier accumulation side diffusion layer 91 so that a light irradiation area to the photodiode 11 can be obtained.

According to the first embodiment of the invention, it is possible to allocate the area for the reset transistor to the area of the amplification transistor 13. For this reason, according to the first embodiment of the invention, it is possible to increase the area of the amplification transistor 13 in comparison with the related art. As a result, it is possible to reduce generation of noise 1/f which increases as the size of the amplification transistor is reduced, and it is possible to provide a high-quality CMOS image sensor with less image noise.

In addition, if the time width of the voltage VSS of the pulse voltage is unnecessarily long, energy is consumed to raise the entire electric potential of the P-type Si substrate so that efficiency is degraded. For this reason, it is preferable that the time width of the pulse voltage is set to a minimum time necessary to fix the electric potential of the carrier accumulation side diffusion layer 91 to the reference voltage Vc.

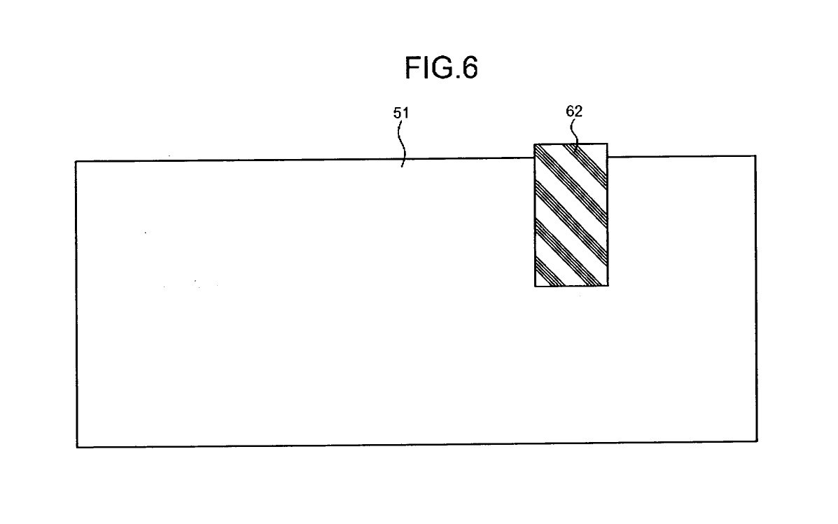

Next, a method of manufacturing a solid-state imaging device for the unit pixel 10 part in the CMOS image sensor according to the first embodiment of the invention will be described. FIGS. 6 to 12 are diagrams illustrating a method of manufacturing a solid-state imaging device including a unit pixel 10 of FIG. 1.

First, using a P-type Si substrate of a resistivity of 1 Ω·cm having a (100) facet on a surface as the substrate 51, a element isolation 62 such as STI having a depth of 3000 angstrom is formed on the substrate 51 (refer to FIG. 6).

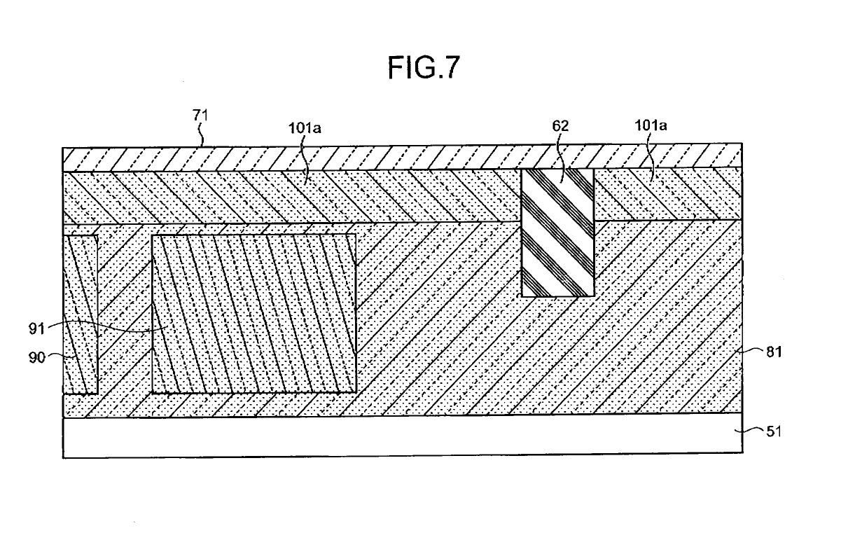

Then, a silicon oxidation film 71 serving as a protection film is formed by oxidizing the substrate 51. Subsequently, P-type boron is ion-implanted into the entire surface of the substrate 51, and an annealing process is performed at a high temperature of about 1000° C. for several minutes, so that an electrolysis layer 81 for electrically separating the photodiode 11 is formed (refer to FIG. 7). In this case, boron is doped using ion implantation with multiple stages at an accelerated voltage to surround all sides of the carrier accumulation side diffusion layer 91 of the photodiode 11 formed after this process, and the annealing condition is adjusted such that a sufficient diffusion distance of the impurities can be obtained. Then, a desired pattern is formed using, a resist, and N-type phosphorus is doped using ion implantation. Subsequently, the carrier accumulation side diffusion layers 91 and 90 of the photodiode 11 are formed to have a depth of, for example, 0.2 μm from the Si surface by performing activation annealing after removing the resist.

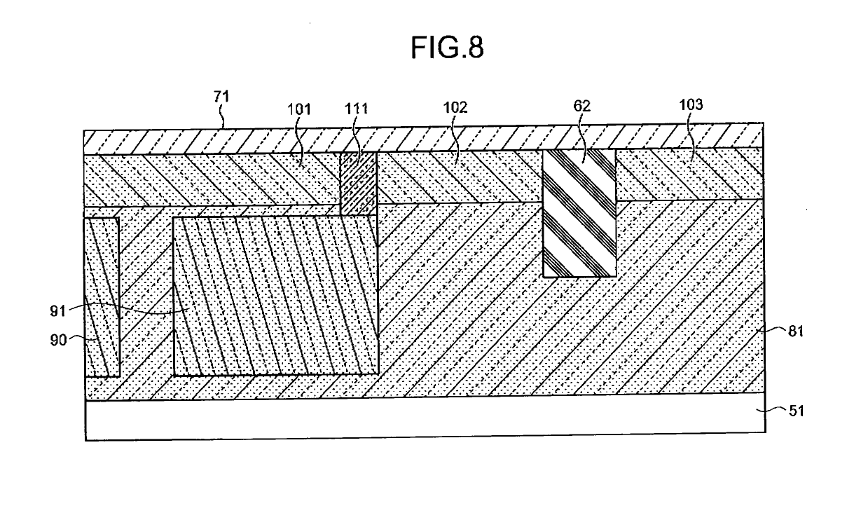

Then, P-type boron ions are implanted into the entire surface of the substrate 51 to form the diffusion layer 101a serving as the well 101 and the channels 102 and 103. After forming a desired pattern using the resist, phosphorus ions are implanted, and the resist is removed. Then, a buried N-type diffusion layer 111 for connecting the carrier accumulation side diffusion layer 91 of the photodiode 11 to the read transistor 12 is formed by performing activation annealing (refer to FIG. 8).

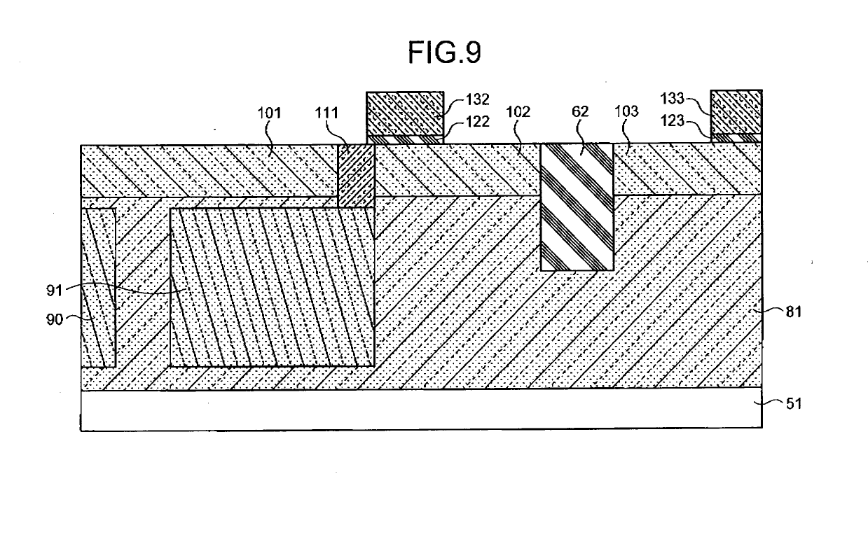

After removing the silicon oxidation film 71, a gate oxide layer is formed. Subsequently, poly-silicon is deposited with a height of about 1500 angstrom and processed to provide a desired shape so that the gate electrodes 132 and 133 of the amplification transistor 13 and the read transistor 12 are formed on the substrate with the gate oxide layers 122 and 123 being interposed (refer to FIG. 9).

After coating the resist and forming a desired pattern, phosphorous ions are implanted into the source side of the read transistor 12 and both sides of the amplification transistor 13 to form the LDD diffusion layers 142 and 143. Then, an activation process is performed after removing the resist. Subsequently, the side walls 152 and 153 are formed by depositing a TEOS oxidation film and applying a RIE process to etch-back the entire surface.

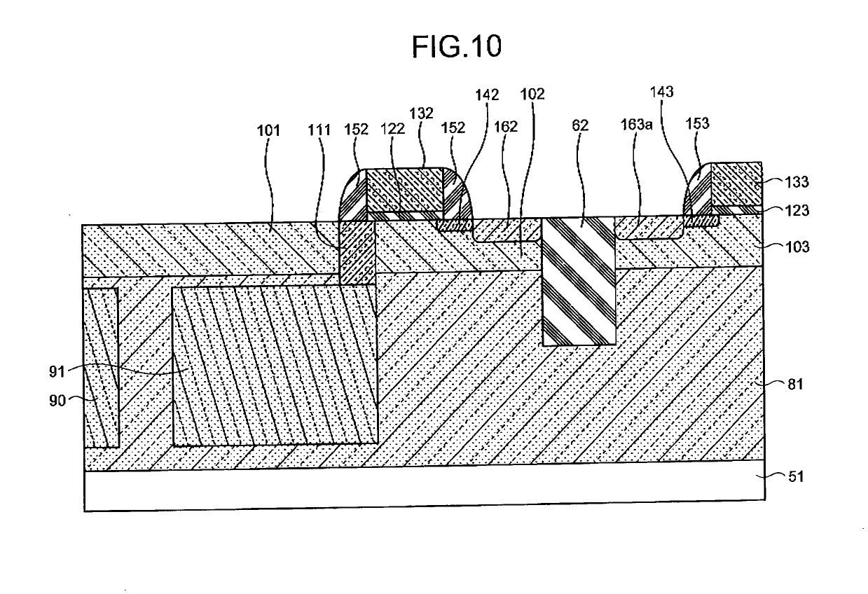

Phosphorus ions are implanted into the source side of the read transistor 12 and both sides of the amplification transistor 13, and activation annealing is performed. As a result, the N+ diffusion layers 162, 163a, and 163b for forming the source-drain region are formed to provide a transistor element (refer to FIG. 10).

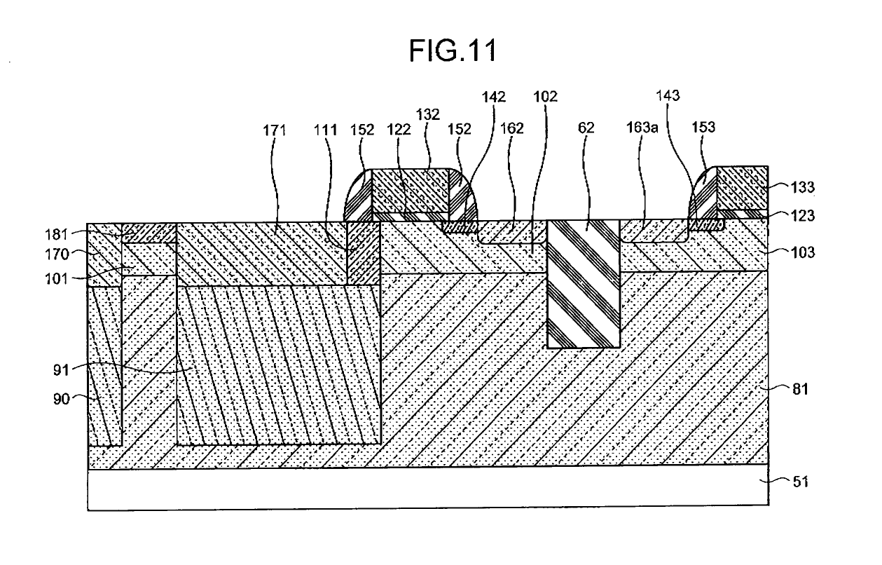

Subsequently, boron ions are implanted by adjusting the acceleration voltage, and the activation annealing is performed. As a result, a p-type shield diffusion layer 171 for preventing pickup of a noise signal caused by an interface state when the carrier accumulation side diffusion, layer 91 makes contact with an interface state of the interface of the substrate 51 is formed across from the surface of the substrate 51 to the upper portion of the carrier accumulation side diffusion layer 91. Then, additional boron ions are implanted into the upper portion of the well 101 for electrically separating the photodiode 11, and activation annealing is applied, so as to form a P-type contact bonding layer 181 (refer to FIG. 11). This contact bonding layer 181 acts to obtain an excellent ohmic contact resistance with the barrier metal layer 211 of the metal contact plug that will be formed subsequently. For example, a boron concentration of the contact bonding layer 181 is set to be equal to or higher than 1×10²⁰ per cm³.

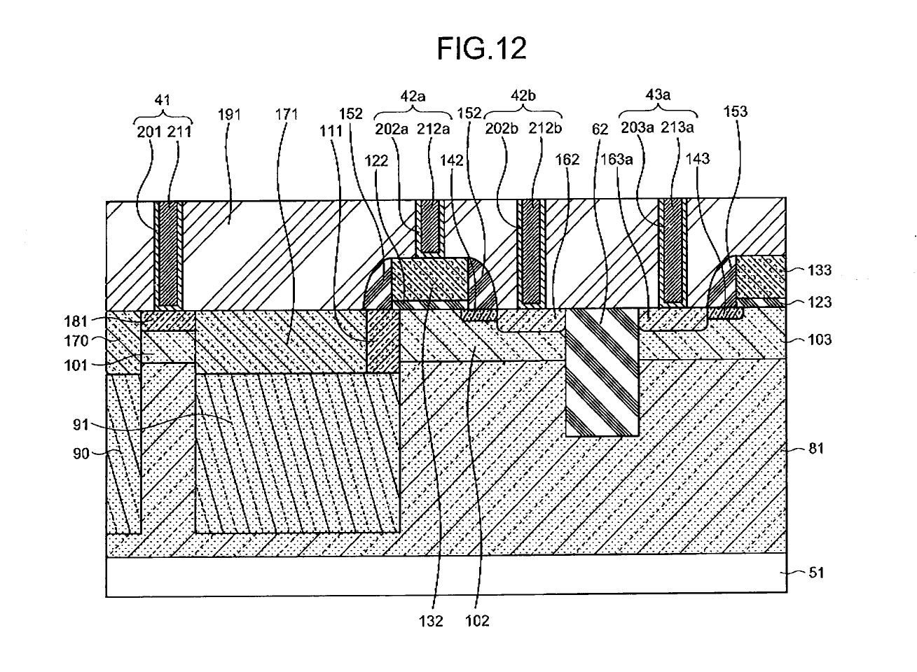

Subsequently, the TEOS oxidation film serving as the interlayer film 191 is deposited and planarized through CMP, and then contact holes are formed on the transistor portion and the contact bonding layer 181. After opening the contact hole, two-layered (Ti(titanium)/TiN(titanium nitride)) barrier metal layers 211, 212a, 212b, and 213a to 213c are formed through sputtering. Metal films 201, 202a, 202b, and 203a to 203c containing tungsten (W) are deposited through a CVD method, and remnants of W and Ti/TiN on the upper layer is removed through CMP so that the contacts 41, 42a, 42b, and 43a to 43c are formed (refer to FIG. 12). Then, the TEOS oxidation film serving as the interlayer film 221 is deposited, and the wiring lines 231, 232a, 232b, and 233a to 233c formed of Cu (copper) are formed in a desired shape through a damascene method. Subsequently, a protection film 241 such as a SiN film for suppressing diffusion of Cu is deposited so that a pixel cell of the CMOS image sensor of FIG. 4 can be completed.

In addition, the CMOS image sensor according to the first embodiment of the invention may be applied to either the front side illumination type or the rear side illumination type. In case of the rear side illumination type, a shield diffusion layer adjoining the carrier accumulation side diffusion layers 90 and 91 may be formed also on the rear sides of the carrier accumulation side diffusion layers 90 and 91.

### Second Embodiment

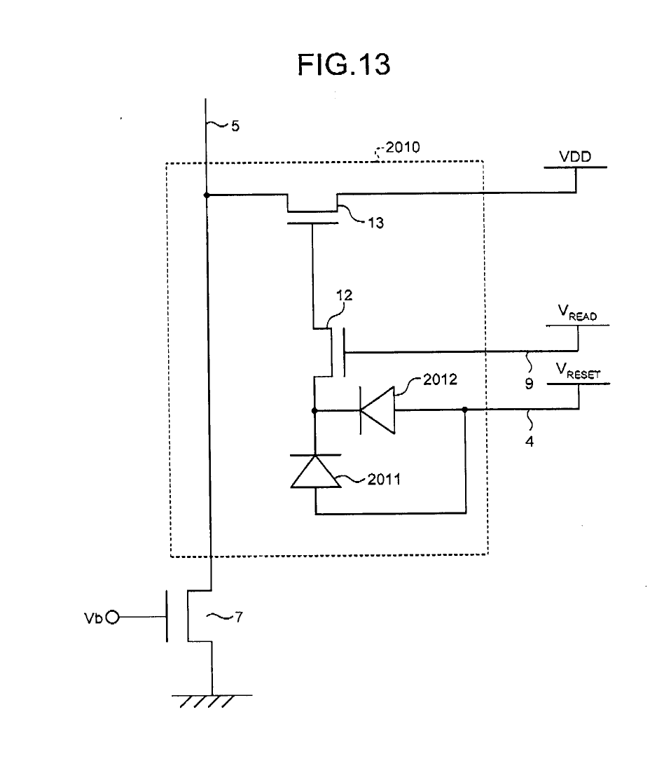

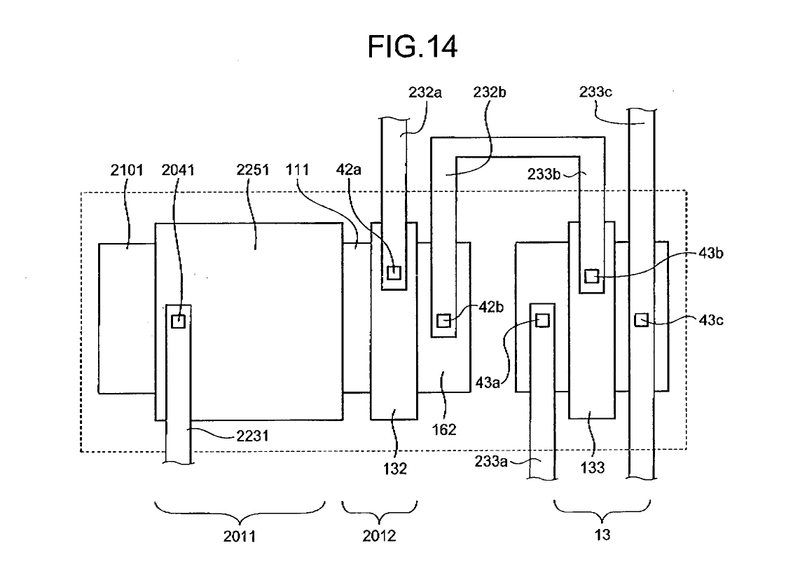

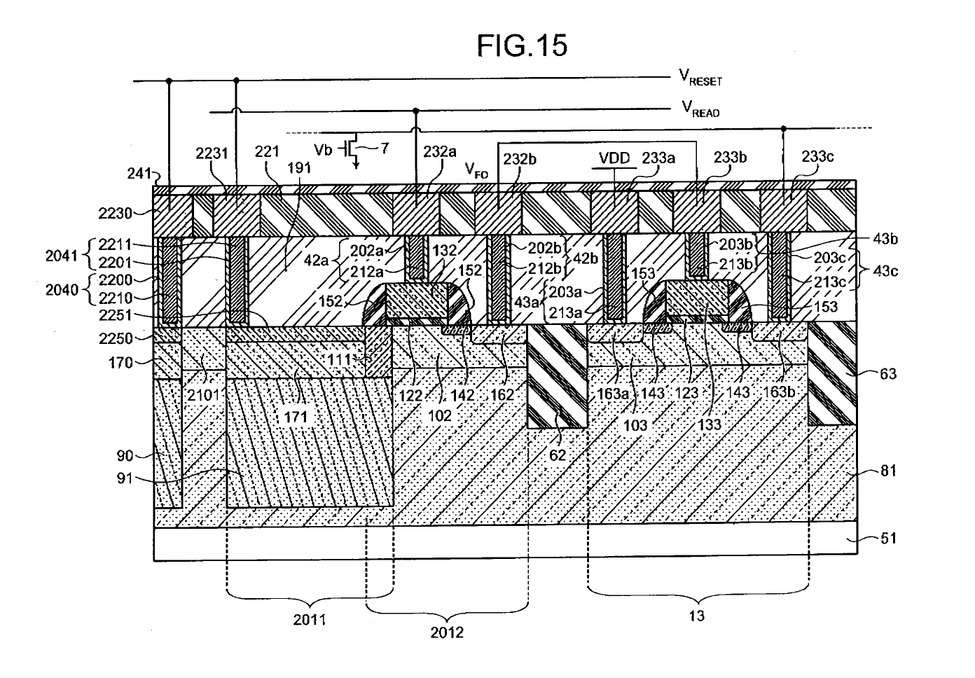

Next, a second embodiment of the invention will be described. FIG. 13 is an equivalent circuit diagram illustrating a configuration of the unit pixel according to a second embodiment of the invention. FIG. 14 is a plan view illustrating a unit pixel of FIG. 13. FIG. 15 is a diagram illustrating a cross-sectional structure of the area corresponding to a single pixel of the solid-state imaging device of the CMOS image sensor according to a second embodiment of the invention. In FIG. 14, the uppermost protection film, the interlayer films for burying each of gaps between each gate terminal layers and gaps between wiring layers, and the side walls are not shown intentionally.

As shown in FIG. 13, in the unit pixel 2010 according to a second embodiment of the invention, a diode 2012 having a function of suppressing the interface state of the substrate is connected between the anode terminal and the cathode terminal of the photodiode 2011.

An actual structure of the unit pixel 2010 according to a second embodiment of the invention has a P-type contact bonding layer 2251 as shown in FIGS. 14 and 15. The contact bonding layer 2251 is formed not on the well 2101 on the P-type electrolysis layer 81 which electrically separates the photodiode 2011 but on the shield diffusion layer 171.

A contact 2041 is formed on the contact bonding layer 2251. A wiring line 2231 for connecting to the reset signal line 4 is formed on the contact 2041. Similar to other contacts 42a, 42b, and 43a to 43c, the contact 2041 has a structure in which the barrier metal layer 2211 is formed around the metal film 2201. Similarly, the neighboring unit pixel shown in the left side of FIG. 15 also has a P-type contact bonding layer 2250 formed on the shield diffusion layer 170, a contact 2040 in which the barrier metal layer 2210 is formed around the metal film 2200, and a wiring line 2230 connected to the reset signal line 4.

Similar to the first embodiment, in the unit pixel 2010 according to the second embodiment, the vertical scanning circuit 2 can read the charges obtained by conversion and accumulation in the carrier accumulation side diffusion layer 91 and fix the voltage of the carrier accumulation side diffusion layer 91 to the reference voltage by applying a voltage at timings shown in FIG. 5.

In case of the read operation, the vertical scanning circuit 2 applies a high-level voltage to the read signal line 9 at a read initiating timing and applies, to the reset signal line 4, a pulse voltage abruptly rising from the voltage VSS to a value higher than a predetermined threshold voltage Vth. This rising voltage is applied to the shield diffusion layer 171 through the wiring line 2231 connected to the reset signal line 4 and the contact bonding layer 2251. In other words, the vertical scanning circuit 2 applies a high-level voltage to the carrier accumulation side diffusion layer 91 through the diode 2012 having a function of suppressing the substrate interface state supposed to exist between the shield diffusion layer 171 and the carrier accumulation side diffusion layer 91.

As a result, similar to the first embodiment, the PN junction formed in the shield diffusion layer 171 and the carrier accumulation side diffusion layer 91 is reverse-biased, and the voltage obtained by adding the reference voltage Vc and the voltage corresponding to the charges obtained by conversion and accumulation in the carrier accumulation side diffusion layer 91 is fixed while the pulse voltage rises, so that the voltage corresponding to the charged obtained by conversion and accumulation in the carrier accumulation side diffusion layer 91 is read.

After the reading, the vertical scanning circuit 2 applies a low-level voltage to the read signal line 9, and applies a voltage abruptly falling from the rising voltage to the voltage VSS to the reset signal line 4. As a result, the PN junction formed in the carrier accumulation side diffusion layer 91 and the shield diffusion layer 171 is reverse-biased, and only the P-type diffusion layer is converged to the voltage VSS while the voltage of the carrier accumulation side diffusion layer 91 is restored and fixed to the reference voltage Vc. Similar to the first embodiment, the vertical scanning circuit 2 serves as a first reference voltage setting unit.

In this manner, according to the second embodiment, the same effects as those of the first embodiment are obtained by providing the contact bonding layer 2251 on the shield diffusion layer 171 and directly applying a pulse voltage which temporally changes to the shield diffusion layer 171.

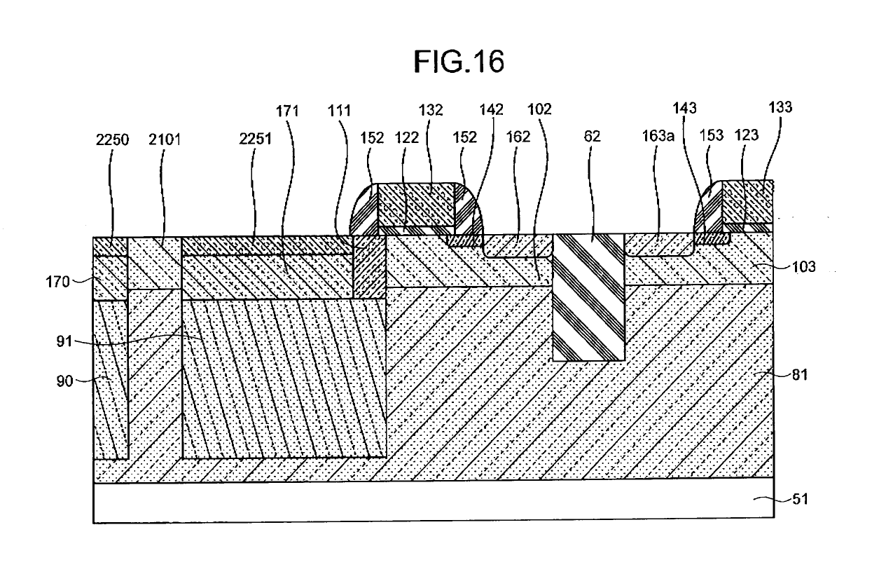

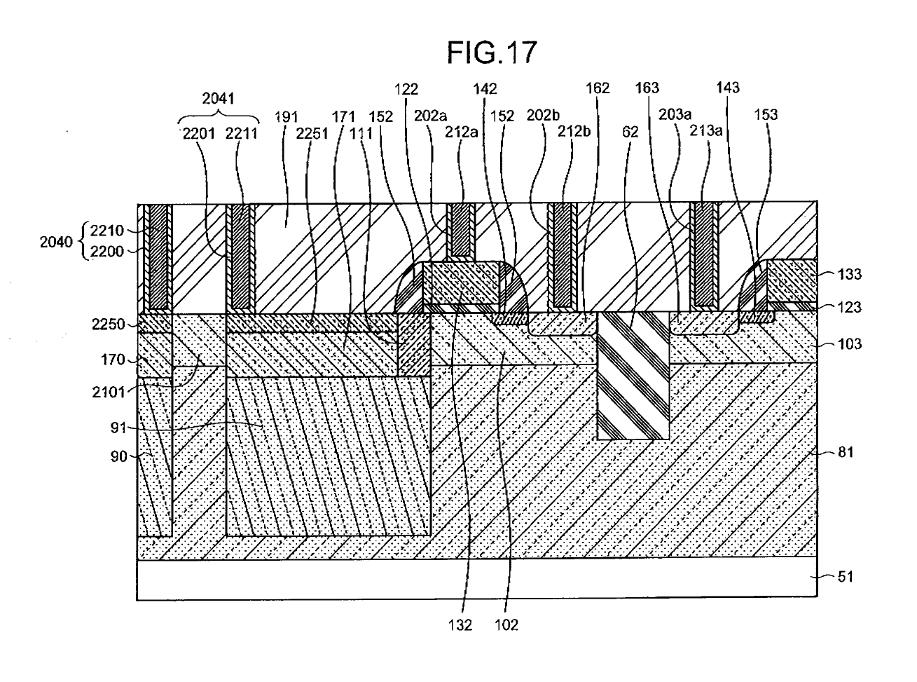

Next, a method of manufacturing the solid-state imaging device in the unit pixel 2010 of the CMOS image sensor according to a second embodiment of the invention will be described. FIGS. 16 and 17 are diagrams illustrating a method of manufacturing a solid-state imaging device including a part of the unit pixel 2010.

Similarly, according to the second embodiment, each process that has been described in conjunction with FIGS. 6 to 10 of the first embodiment is performed, and the side walls 152 and 153 of the gate electrodes 132 and 133 of the amplification transistor 13 and the read transistor 12 are formed. Subsequently, boron ions are implanted by adjusting the acceleration voltage, and the shield diffusion layer 171 is formed.

In addition, boron ions are further implanted to the upper portion of the shield diffusion layer 171, and activation annealing is carried out so that the P-type well contact bonding layers 2250 and 2251 are formed. The contact bonding layers 2250 and 2251 act to obtain an excellent ohmic contact resistance with the barrier metal layer 2211 of the metal contact plug that will be formed subsequently. For example, a boron concentration of the contact bonding layer 2251 is set to be equal to or higher than 1×10²⁰ per cm³, for example, in the area having a depth of 0.1 μm or smaller from the surface of the substrate 51. Then, impurities are activated by performing high-speed temperature-rising annealing about a thousand of times within several seconds (refer to FIG. 16).

Subsequently, the TEOS oxidation film serving as the interlayer film 191 is deposited and planarized through CMP, so that contact holes are formed on the transistor portion and the contact bonding layers 2250 and 2251. After opening the contact hole, the barrier metal layers 2210, 2211, 212a, 212b, and 213a to 213c are deposited through sputtering, and the metal films 2200, 2201, 202a, 202b, and 203a to 203c are deposited through a CVD method. Then, the remnants of W and Ti/TiN of the upper layer are removed so as to form the metal contact plug (refer to FIG. 17).

The TEOS oxidation film serving as the interlayer film 221 is deposited, the wiring lines 231, 232a, 232b, and 233a to 233c formed of Cu (copper) are formed in a desired shape through a damascene method, and then, the protection film 241 is deposited, so that the pixel cell of the CMOS image sensor of FIG. 15 can be completed.

The CMOS image sensor according to the second embodiment of the invention may be applied to either the front side illumination type or the rear side illumination type. In case of the rear side illumination type, a shield diffusion layer adjoining the carrier accumulation side diffusion layer 91 may be formed also on the rear side of the carrier accumulation side diffusion layers 91.

In the case where the CMOS sensor is a front side illumination type in which light is incident from the metal wiring line side, it is preferable that the patterning is performed not to form a shade on the carrier accumulation side diffusion layers 90 and 91 by arranging the contacts 2040 and 2041 and the Cu wiring lines 2230 and 2231 connected thereto in the vicinity of the corner of the photodiode 2011 area, if possible, so as not to interfere incidence of light. In the case where the CMOS sensor is a rear side illumination type in which light is incident from the rear side of the substrate, the contacts 2040 and 2041 are formed on the entire surface of the shield diffusion layers 170 and 171 as much as possible in order to reduce the contact resistance.

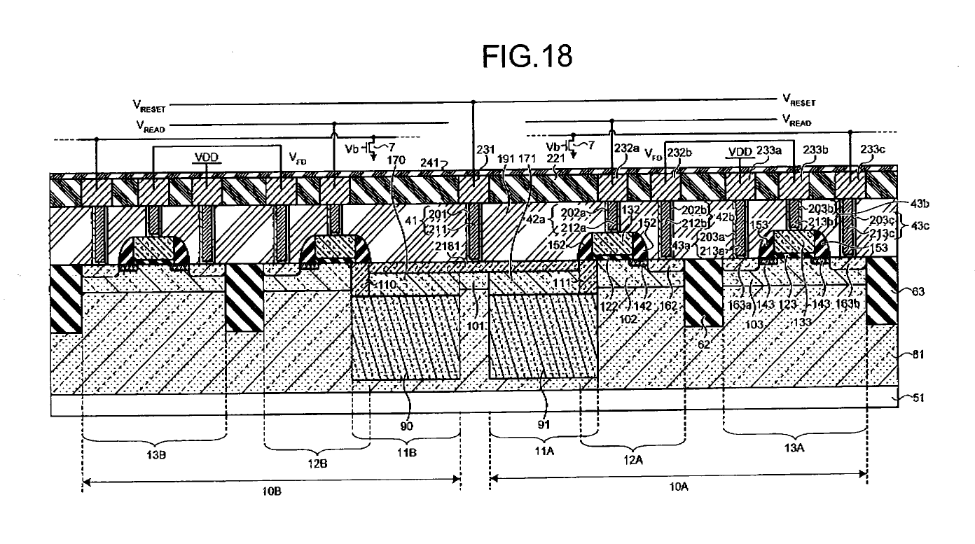

According to the second embodiment, two neighboring unit pixels may share the contact and the wiring line connected to the reset signal line 4. Specifically, as shown in the solid-state imaging device of FIG. 18, the contact bonding layer 2181 is continuously formed on the well 101 and the shield diffusion layers 170 and 171 of two neighboring unit pixels 10A and 10B, and the wiring line 231 connected to the reset signal line 4 and the contact 41 formed on this contact bonding layer 2181 are provided. As a result, the photodiodes 11A and 11B of two neighboring unit pixels 10A and 10B can share the wiring line 231 and the contact 41 connected to the reset signal line 4 for the carrier accumulation side diffusion layers 90 and 91. The two unit pixels 10A and 10B include read transistors 12A and 12B and amplification transistors 13A and 13B, respectively.

### Third Embodiment

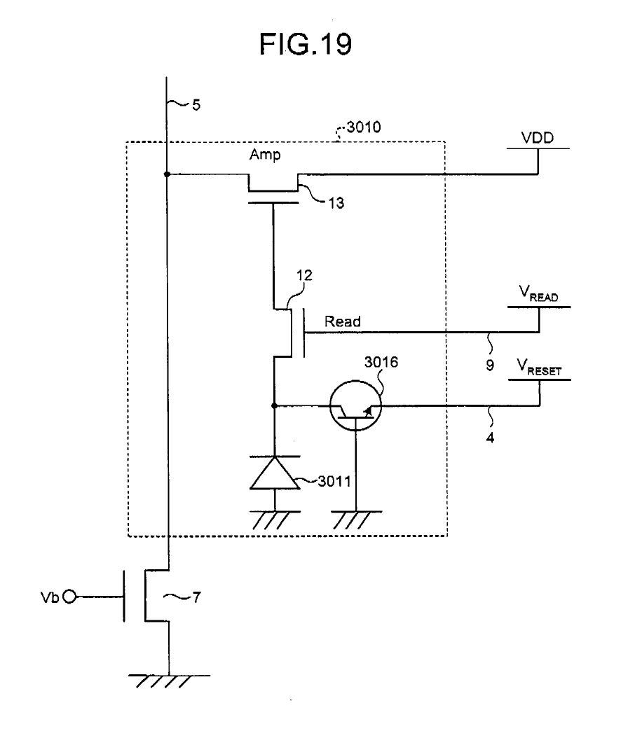

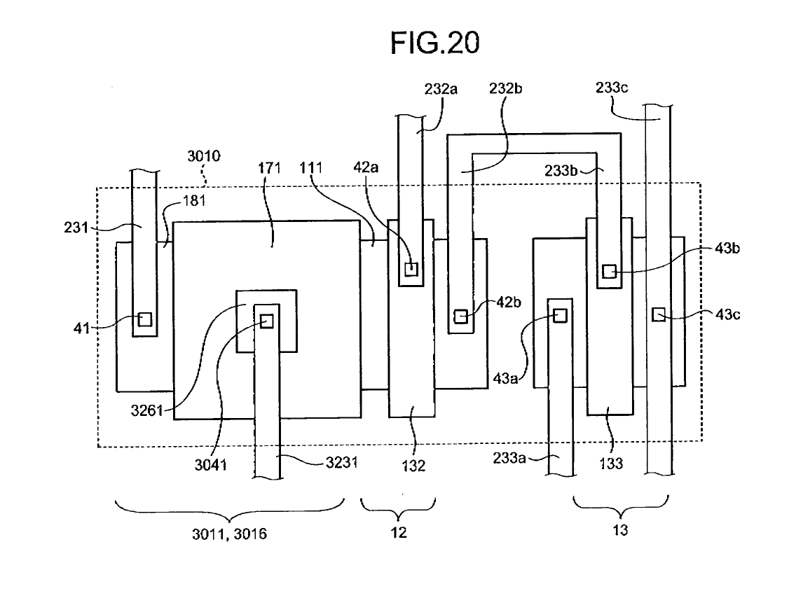

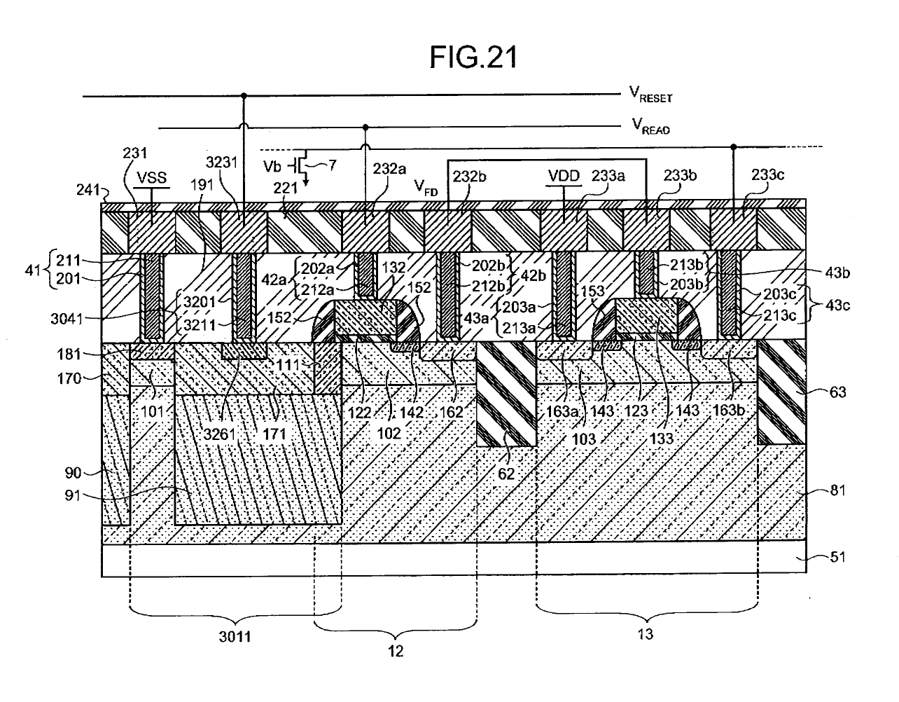

Next, a third embodiment of the invention will be described. FIG. 19 is an equivalent circuit diagram illustrating a configuration of the unit pixel according to a third embodiment of the invention. FIG. 20 is a plan view illustrating a unit pixel of FIG. 19. FIG. 21 is a diagram illustrating a cross-sectional structure of the area corresponding to a single pixel of the solid-state imaging device of the CMOS image sensor according to a third embodiment of the invention. In FIG. 20, the uppermost protection film, the interlayer films for burying each of gaps between each gate terminal layers and gaps between wiring layers, and the side walls are not shown intentionally.

As shown in FIG. 19, in the unit pixel 3010 according to a third embodiment of the invention, the anode terminal of the photodiode 3011 is connected to the ground, and the cathode terminal of the photodiode 3011 is connected to the reset signal line 4 through the connector 3016.

An actual structure of the unit pixel 3010 according to a third embodiment of the invention further includes an N-type reset diffusion layer 3261 having the same polarity as that of the carrier accumulation side diffusion layer 91 on the shield diffusion layer 171 as shown in FIGS. 20 and 21 in comparison with the solid-state imaging device of FIG. 4 according to the first embodiment of the invention. A contact 3041 is formed on the reset diffusion layer 3261. A wiring line 3231 connected to the reset signal line 4 is formed on the contact 3041. Similar to other contacts 41, 42a, 42b, and 43a to 43c, the contact 3041 has a structure in which the barrier metal layer 3211 is formed around the metal film 3201.

In this unit pixel 3010, the vertical scanning circuit 2 applies a pulse voltage temporally abruptly changing up and down to the reset diffusion layer 3261 while the voltage VSS is applied to the P-type contact bonding layer 181.

Here, in the case where the voltage applied by the vertical scanning circuit 2 remains in a predetermined falling voltage, no electric current flows because a P-type layer (shield diffusion layer 171) exists between the carrier accumulation side diffusion layer 91 and the reset diffusion layer 3261 while its electric potential is fixed. Therefore, the reset diffusion layer 3261 and the carrier accumulation side diffusion layer 91 are insulated. In this state, the scanning circuit unit 2 applies a high-level voltage to the read signal line to turn the read transistor on so as to read a voltage fixed to the value obtained by adding the reference voltage Vc and the voltage corresponding to the charges obtained by conversion and accumulation in the carrier accumulation side diffusion layer 91.

From this state, as the scanning circuit unit 2 starts raising the voltage applied to the reset signal line 4, a depletion layer is connected between the reset diffusion layer 3261 and the carrier accumulation side diffusion layer 91 at a predetermined voltage value so that a punch-through voltage flows. As a result, the signal line 4 is connected to the photodiode 3011. In this manner, the charges accumulated in the carrier accumulation side diffusion layer 91 are discharged to the ground by connecting the photodiode 3011 and the signal line 4 so that the voltage of the carrier accumulation side diffusion layer 91 is restored and fixed to the reference voltage.

The connector 3016 connects the reset signal line 4 and the photodiode 3011 using the punch-through phenomenon between the reset diffusion layer 3261 and the carrier accumulation side diffusion layer 91 during a rising time of the pulse voltage caused by the reset signal line 4.

The vertical scanning circuit 2 sets the voltage of the carrier accumulation side diffusion layer 91 to the reference voltage by applying a rising voltage to the reset diffusion layer 3261 through the reset signal line 4 and flowing an electric current to the carrier accumulation side diffusion layer 91 through the shield diffusion layer 171.

The vertical scanning circuit 2 sets the reference voltage for the carrier accumulation side diffusion layer 91, drops the voltage applied to the reset signal line 4, insulates the reset diffusion layer 3261 and the carrier accumulation side diffusion layer 91 again, and then, performs the next read process. The vertical scanning circuit 2 is connected to the reset diffusion layer 3261 through the wiring line 3231 and applies the pulse voltage to the carrier accumulation side diffusion layer 91 by applying the pulse voltage to the reset diffusion layer 3261 through the wiring line 3231 so as to serve as a second reference voltage setting unit for setting a voltage based on the amplitude of the applied pulse voltage as the reference voltage of the carrier accumulation side diffusion layer 91.

In this manner, according to the third embodiment of the invention, the vertical scanning circuit 2 punches through the gap between the reset diffusion layer 3261 and the carrier accumulation side diffusion layer 91 by applying the pulse voltage of the reset diffusion layer 3261 to fix the carrier accumulation side diffusion layer 91 to the reference voltage. For this reason, the vertical scanning circuit 2 is terminated just by applying a voltage that can generate a punch-through phenomenon when the reference voltage of the carrier accumulation side diffusion layer 91 is set. As a result, according to the third embodiment of the invention, it is possible to reduce the applied voltage in comparison with the first and second embodiments in which a voltage is applied to the P-type well and realize an initialization operation with excellent energy efficiency.

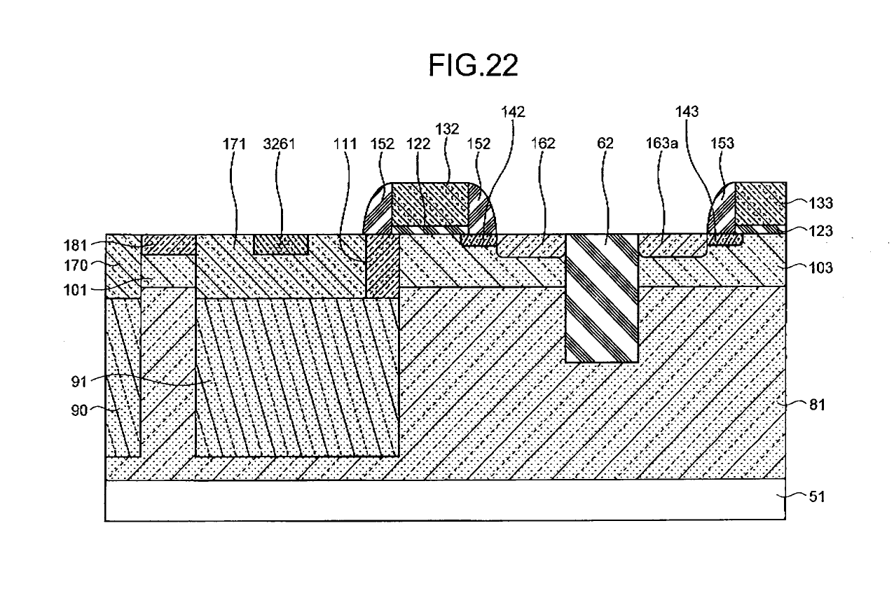

Next, a method of manufacturing the solid-state imaging device in the unit pixel 3010 portion in the CMOS image sensor according to a third embodiment of the invention will be described. FIG. 22 is a diagram illustrating a method of manufacturing a solid-state imaging device including a part of the unit pixel 3010.

Similarly, according to the third embodiment of the invention, each process that has been described in conjunction with FIGS. 6 to 11 is performed to form a read transistor 12, a transistor element of an amplification transistor 13, a shield diffusion layer 171, and a contact bonding layer 181.

Next, phosphorus ions are implanted with a low acceleration voltage of about 10 KeV, and then, activated by performing high-speed temperature-rising annealing about a thousand of times within about one second so as to form a shallow reset diffusion layer 3261 having a diffusion layer having a depth of 0.1 μm or lower and a concentration of 1×10²⁰ per cm³ or higher. Here, it is necessary to maintain a distance of 0.1 μm or longer between the reset diffusion layer 3261 and the carrier accumulation side diffusion layer 91 in a vertical cross-sectional view. It is also necessary to arrange the reset diffusion layer 3261 with a sufficient distance from the P-type contact bonding layer 181 in a plan view.

Then, each process described in conjunction with FIG. 12 is performed to form the interlayer films 191 and 221, the contacts 41, 42a, 42b, 43a to 43c, and 3041, the wiring lines 231, 232a, 232b, 233a, 233b, and 3231, and the protection film 241 so that a pixel cell of the CMOS image sensor of FIG. 21 can be completed.

The CMOS image sensor according to the third embodiment of the invention may be applied to either the front side illumination type or the rear side illumination type.

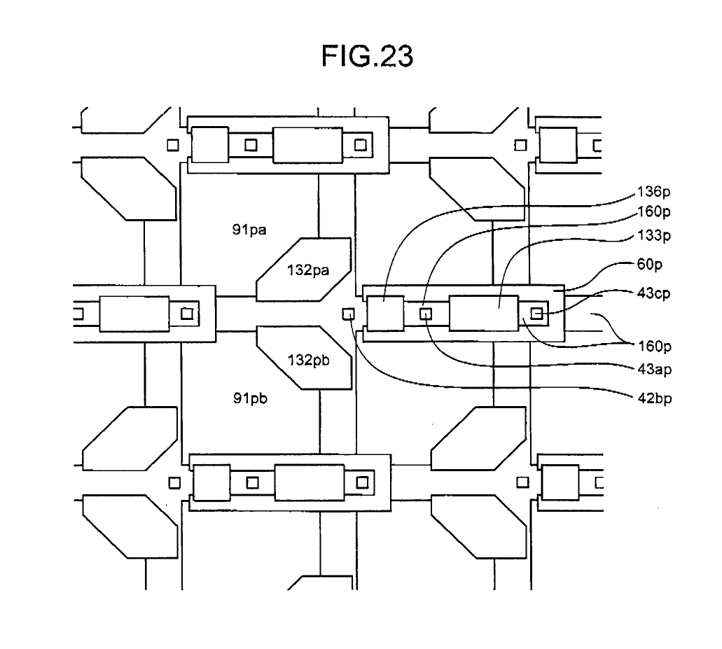

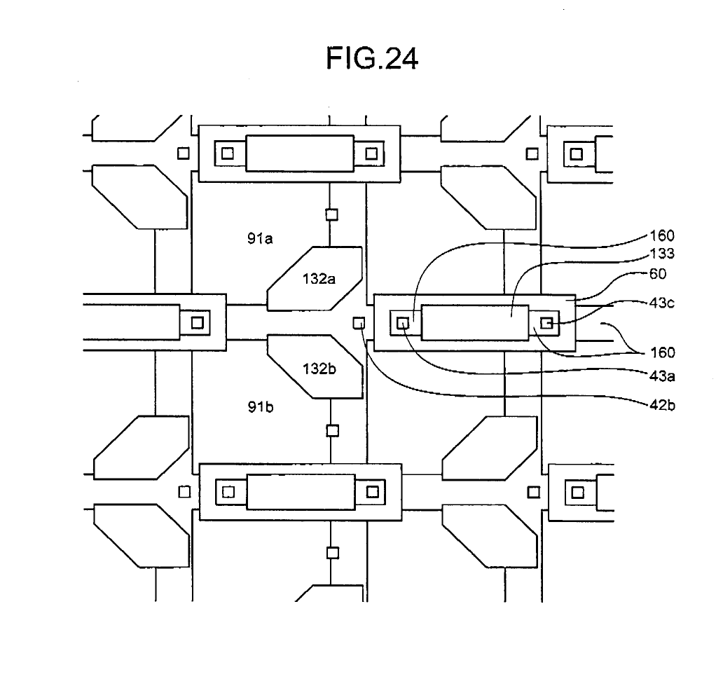

The first to third embodiments of the invention may also be applied to the two-pixel one-cell structure. FIG. 23 is a plan view illustrating the CMOS image sensor having a two-pixel one-cell structure of the related art. FIG. 24 is a plan view illustrating the CMOS image sensor when the first embodiment of the invention is applied to the two-pixel one-cell structure. In FIGS. 23 and 24, the uppermost protection film, the interlayer films for burying each of gaps between each gate terminal layers and gaps between wiring layers, and the side walls are not shown intentionally.

As shown in FIG. 23, in the related art, the reference voltage of the carrier accumulation side diffusion layer is fixed in pixel unit further including the reset transistor (in FIG. 23, the gate electrode is denoted by the reference numeral 136p) in addition to two carrier accumulation side diffusion layers 91pa and 91pb, the read transistor formed on the well 160p (in FIG. 23, gate electrodes are denoted by the reference numerals 132pa and 132pb), and a single amplification transistor (in FIG. 23, the gate electrode is denoted by the reference numeral 133p) separated from the read transistor by the element isolation 60p.

In contrast, when the first embodiment of the invention is applied, for the read transistor (in FIG. 24, the gate electrodes are denoted by reference numerals 132a and 132b) formed on the well 160 and the two carrier accumulation side diffusion layers 91a and 91b, only a single amplification transistor (in FIG. 24, the gate electrode is denoted by the reference numeral 133) separated from the read transistor (in FIG. 24, the gate electrodes are denoted by the reference numerals 132a and 132b) by the element isolation 60 may be provided.

In addition, while a case where the substrate 51 is a P-type, and the carrier accumulation side diffusion layers 90 and 91 are an N-type has been described for the embodiments 1 to 3, the same effect can be obtained even in the structure in which the N-type and the P-type of the semiconductor are reversed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a photodiode formed on a substrate, the photodiode having a first diffusion layer for accumulating carriers generated by a photoelectric effect;
a second diffusion layer adjoining the first diffusion layer, the second diffusion layer having polarity opposite to that of the first diffusion layer; and
a first reference voltage setting unit connected to the second diffusion layer through a wiring line, the first reference voltage setting unit applying a changing voltage to the first diffusion layer by applying the changing voltage that temporally changes to the second diffusion layer through the wiring line, and setting a voltage based on an amplitude of the applied changing voltage as a reference voltage of the first diffusion layer.

2. The solid-state imaging device according to claim 1,
wherein the second diffusion layer is a shield diffusion layer for protecting the first diffusion layer from an interface state of the substrate.

3. The solid-state imaging device according to claim 1,
wherein the first diffusion layer is surrounded by a diffusion layer which is equal to the second diffusion layer in polarity, the diffusion layer including at least the second diffusion layer.

4. The solid-state imaging device according to claim 3,
wherein the first diffusion layer is surrounded by the second diffusion layer and an electrolysis layer electrically separating the photodiode.

5. The solid-state imaging device according to claim 1, further comprising a third diffusion layer connected to the second diffusion layer, the third diffusion layer being equal to the second diffusion layer in polarity.

6. The solid-state imaging device according to claim 5,
wherein the first reference voltage setting unit applies the changing voltage to the first diffusion layer through the second diffusion layer by applying the changing voltage to the third diffusion layer.

7. The solid-state imaging device according to claim 5,
wherein the third diffusion layer is a well of the solid-state imaging device.

8. The solid-state imaging device according to claim 5,
wherein the second diffusion layer is a shield diffusion layer for protecting the first diffusion layer from an interface state of the substrate, and
the third diffusion layer is a layer formed on the shield diffusion layer and a layer to which impurities equal to the shield diffusion layer in polarity are added with a higher concentration than that of the shield diffusion layer.

9. The solid-state imaging device according to claim 1,
wherein the first reference voltage setting unit applies a pulse voltage having an amplitude equal to or higher than the reference voltage.

10. The solid-state imaging device according to claim 9,
wherein the pulse voltage has an amplitude of a value obtained by adding a predetermined threshold voltage and a voltage value obtained by considering a voltage drop.

11. The solid-state imaging device according to claim 10,
wherein the first reference voltage setting unit fixes a voltage of the first diffusion layer to a voltage obtained by adding the reference voltage and a voltage corresponding to charges accumulated by the first diffusion layer by applying a voltage equal to or higher than the predetermined threshold voltage.

12. The solid-state imaging device according to claim 10,
wherein the first reference voltage setting unit fixes a voltage of the first diffusion layer to the reference voltage by applying a VSS voltage.

13. A solid-state imaging device comprising:
a photodiode formed on a substrate, the photodiode having a first diffusion layer for accumulating carriers generated by a photoelectric effect;
a second diffusion layer adjoining the first diffusion layer, the second diffusion layer having polarity opposite to that of the first diffusion layer;
a fourth diffusion layer formed on the second diffusion layer, the fourth diffusion layer being equal to the first diffusion layer in polarity; and
a second reference voltage setting unit connected to the fourth diffusion layer through a wiring line, the second reference voltage setting unit applying a changing voltage to the first diffusion layer by applying a changing voltage that temporally changes to the fourth diffusion layer through the wiring line and setting a voltage based on an amplitude of the applied changing voltage as a reference voltage of the first diffusion layer.

14. The solid-state imaging device according to claim 13,
wherein the second diffusion layer is a shield diffusion layer for protecting the first diffusion layer from an interface state of the substrate.

15. The solid-state imaging device according to claim 13,
wherein the first diffusion layer is surrounded by a diffusion layer which is equal to the second diffusion layer in polarity, the diffusion layer including at least the second diffusion layer.

16. The solid-state imaging device according to claim 15,
wherein the first diffusion layer is surrounded by the second diffusion layer and an electrolysis layer electrically separating the photodiode.

17. The solid-state imaging device according to claim 13,
wherein the second reference voltage setting unit applies a pulse voltage having an amplitude equal to or higher than the reference voltage.

18. The solid-state imaging device according to claim 17,
wherein the pulse voltage has an amplitude of a value obtained by adding a predetermined threshold voltage and a voltage value obtained by considering a voltage drop.

19. The solid-state imaging device according to claim 18,
wherein the second reference voltage setting unit applies a voltage equal to or higher than the predetermined threshold voltage to the fourth diffusion layer so as to connect the first diffusion layer and the fourth diffusion layer via a depletion layer to allow flowing of a punch-through current such that a voltage of the first diffusion layer is fixed to the reference voltage.

20. The solid-state imaging device according to claim 18,
wherein the second reference voltage setting unit fixes a voltage of the first diffusion layer to a value obtained by adding a voltage corresponding to charges accumulated in the first diffusion layer and the reference voltage by applying a VSS voltage.
